(19) United States
(12) Patent Application Publication
(10) Pub. No.: US 2010/0276071 A1
(43) Pub. Date: Nov. 4, 2010

(54) TANDEM SOLAR CELL

(75) Inventors: Vishal Shrotriya, El Monte, CA (US); Gang Li, El Monte, CA (US)

Correspondence Address: GREENBERG TRAURIG LLP (LA), 2450 COLORADO AVENUE, SUITE 400E, INTELLECTUAL PROPERTY DEPARTMENT, SANTA MONICA, CA, 90404, US

(73) Assignee: SOLARMER ENERGY, INC., El Monte, CA (US)

(21) Appl. No.: 12/432,665

(22) Filed: Apr. 29, 2009

(51) Int. Cl. B32B 37/10

(52) U.S. Cl. 156/182

(57) ABSTRACT

Two methods to achieve a tandem solar cell are disclosed. The first involves stacking together two or more complete polymer solar cells, each having a polymer blend active layer. The individual solar cells can be connected either in series or in parallel. In the second method, two individual polymer solar cells are first constructed and then laminated together to form a tandem structure. The lamination can be metal-free, thus resulting in translucent polymer solar cells.

### BACKGROUND

1. Field

This disclosure relates, generally, to solar cells and more particularly to organic solar cells.

2. General Background

The present invention relates to a manufacturing method for a flexible tandem polymer solar cell.

Solar cells based on organic materials and polymers have attracted broad research interest and are considered as promising alternatives to their inorganic counterparts. Among their attractive features, they are low-cost, flexible, have low-energy consumption, incorporate high-throughput processing technologies, they are aesthetically pleasing, and are versatile for many applications.

Polymer or fullerene based bulk-heterojunction (BHJ) polymer solar cells have reached solar cell efficiencies of 5%. However, the efficiency of polymer solar cell is still low compared to inorganic solar cells. One of the efficiency-limiting aspects of polymer solar cell is the normally high optical bandgap, which leads to inefficient absorption of solar irradiation.

### SUMMARY

A lamination process to fabricate multiple-stacking and tandem polymer solar cells is proposed. The process is compatible with flexible substrates and roll-to-roll fabrication. The vacuum evaporation process is eliminated, leading to a low-cost and high throughput process.

The present disclosure includes two methods to achieve tandem structure. The first method involves stacking one polymer solar cell on top of another solar cell where each cell has two electrodes. The two solar cells can be connected in series or in parallel. The second method involves laminating two polymer solar cells together where each cell has only one electrode to form a tandem polymer solar cell. The lamination process can be metal-free, thus allowing the solar cell to be translucent. These two methods can also be combined.

Multiple-stacking and tandem polymer solar cells using lamination process have advantages over other polymer solar cell fabrication processes. Such advantages include vacuum-free process that can lower manufacturing cost, compatible with flexible substrates and roll-to-roll fabrication, compatible with transparent (translucent) polymer solar cells and higher solar cell efficiency is possible through improved light harvesting with multiple active layers.

### DRAWINGS

The above-mentioned features and objects of the present disclosure will become more apparent with reference to the following description taken in conjunction with the accompanying drawings wherein like reference numerals denote like elements and in which:

FIG. 1a is an embodiment of a sub-cell with one electrode in accordance with the present disclosure.

FIG. 1b is an embodiment of a sub-cell with one electrode in accordance with the present disclosure.

FIG. 1c shows two sub-cells being laminated together in accordance with the present disclosure.

FIG. 2 is a diagram that represents the relationship of the absorption range for two polymers used for active layers in accordance with the present disclosure.

FIG. 3 is an embodiment of two sub-cells before they are laminated together in accordance with the present disclosure.

FIG. 4 is a flow diagram for a method of fabricating a multiple stacking solar cell in accordance with the present disclosure.

FIG. 5 is an embodiment of two sub-cells before they are laminated together in accordance with the present disclosure.

FIG. 6 is an embodiment of a tandem solar cell in accordance with the present disclosure.

FIG. 7 is a flow diagram for a method of fabricating a tandem solar cell in accordance with the present disclosure.

FIG. 8 is an embodiment of two sub-cells before they are laminated together in accordance with the present disclosure.

FIG. 9 shows a multiple layer structure, in accordance with the present disclosure, with repeated plastic and thermal curable resin units.

### DETAILED DESCRIPTION

Two methods to achieve a tandem solar cell are disclosed. The first method involves stacking two or more complete polymer solar cells (each having a polymer blend active layer) together. The individual solar cells can be connected either in series or in parallel. In the second method, two individual polymer solar cells are first constructed and then laminated together to form a tandem structure. The lamination can be metal-free, thus resulting in translucent polymer solar cell. Techniques of the two methods can also be combined.

In the present disclosure, “thermal annealing” refers to a process in which the substrates, which have various layers deposited on top, are provided thermal energy (heat) by placing the substrates on a hot plate, which is maintained at a certain temperature for a certain period of time. The temperature is referred to as the annealing temperature and the time as annealing time. The thermal annealing may also be done by providing the thermal energy in non-contact mode where the substrate does not come in contact with the hot plate (or heat source), such as placing the substrates in an oven under controlled temperature for a certain period of time.

In the present disclosure, “solvent annealing” refers to a process where an organic layer, which has been deposited on top of a substrate that has a bottom contact deposited by solution processing, is allowed to solidify at a controlled slow rate to enhance the self-organization in the organic polymer film. This is achieved by dissolving the organic polymer(s) in a high boiling-point solvent, such as chlorobenzene, dichlorobenzene or tricholorobenzene, for depositing the organic polymer film by solution processing. Due to the high boiling point of the solvent, the film is usually wet after it is deposited, which is then allowed to dry in a controlled manner to slow down the time it takes for the film to convert from liquid phase to solid phase. The desired solidification time is between 1 to 20 minutes. The longer solidification time allows the polymer chains in film to align in a highly-ordered crystalline phase which may result in increased efficiency of photovoltaic conversion in the film.

In the present disclosure, additives can be added to enhance carrier mobility. Adding additives is a technique used in polymer solar cells to improve the morphology and enhance the carrier mobility. One example is adding a slight amount of poor solvent(s) (e.g., alkanedithiols, or nitrobenzene) into the dominant solvent used to make polymer solution (e.g., chlorobenzene or dichlorobenzene). Improved polymer aggregation and crystallinity has been achieved in some polymer systems and so has enhanced carrier mobility. Another example is the addition of electrolytes and salt into polymer blend solutions, which is also shown to improve photocurrent in polymer solar cells.

In the present disclosure, “thermal evaporation” refers to a common technique, one of the physical vapor deposition (PVD) methods, to deposit thin film materials. In thermal evaporation, the material is heated in a vacuum typically of 10⁻⁵ to 10⁻⁷ Torr range until it melts and starts evaporating. The vapor then condenses on a substrate exposed to the vapor, which is kept at a cooler temperature to form a thin film. The materials are heated by placing them in a crucible (or boat) which is made of high electrical resistance material such as tungsten, and passing high current through the boat. The active layer(s) of organic solar cells include a p-type electron donor material and an n-type electron acceptor material, either as separate layers or in a mixture layer or the active layer could be a combination thereof.

The term “organic material” can be any type of organic, metal-organic and/or inorganic synthetic materials, which are sometimes called “plastics.” This includes all types of materials except semiconductors used for conventional diodes (germanium, silicon) and typical metallic conductors.

The conductive semitransparent or translucent layer of organic material can be a conjugated polymer that is not conductive, but is made conductive by the addition of conductive fillers. Other alternatives are organic materials that are applied by means of solvents and/or a vacuum process and that provide the necessary conductivity and translucence.

One advantage of tandem solar cells is that the spectral absorption of the solar cell can be broadened by using two solar cells connected in series. If, for example, semiconductors with different bandgaps are used for the two sub-cells, the total absorption that results for the cell essentially represents a superposition of the individual or half-cells. Such a configuration would include a first semiconductor having a large bandgap with absorption toward the blue end of the spectrum and a second semiconductor having a small bandgap with absorption toward the red end of the spectrum.

Typically, polymer solar cells utilize a bulk-heterojunction (BHJ) of a p-type donor polymer and an n-type acceptor material. The photons are absorbed in the donor polymer and/or acceptor, and the excitons are generated upon photo-absorption. The generated excitons migrate to the donor-acceptor interface, where they are dissociated into free electrons and holes. The excitations are then transported through a 3-dimensional (3-D) interpenetrated network of donor and acceptor in the BHJ film and are collected at the contacts.

Many polymers can be used as the donor for the BHJ film, such as P3HT, poly[2-methoxy-5-(3,7-dimethyloctyloxy)-1,4-phenylene vinylene] (MDMO-PPV), or poly(2-methoxy-5-(2′-ethyl-hexyloxy)-1,4-phenylene vinylene) (MEH-PPV). The bandgap of polymers are normally higher than the materials used in inorganic solar cells. For example, P3HT has bandgap of 1.9 ev, compared to 1.1 ev of silicon. The higher bandgap leads to less efficient light harvesting. Low-bandgap polymers have been intensively studied to be used for the active layer and several have shown promise, for example, polymers based on alternating thieno[3,4-b]thiophene and benzodithiophene units and PSBTBT. The integration of high- and low-bandgap polymers in solar cells can lead to higher polymer solar cell performance. The integration can be in the format of tandem cell or multiple-device stacking schemes.

Common candidates for the acceptor materials are PCBM or [6,6]-phenyl C71-butyric acid methyl ester (C70-PCBM) or single-walled carbon nanotubes (CNTs) and other n-type polymers. The p-type electron donor material is typically a polymer, and the n-type electron acceptor material can be either a small organic molecule, such as fullerene (e.g., PCBM), or carbon nanotubes (CNT) or an n-type polymer, or inorganic nanoparticles (NPs) (e.g., ZnO NP, TiOx NP etc.).

The active layer can be obtained by spin-coating from a polymer solution of organic solvent(s). The film can also be obtained by other solution processing techniques, such as but not limited to wired bar-coating, inkjet-printing, doctor-blading, spray coating, screen-printing etc. Combinations of these techniques along with lamination processes can lead to a cost efficient large area polymer solution coating and solar cell formation. The substrate can be flexible and can substitute glass.

To improve the photovoltaic conversion efficiency, the BHJ film may undergo certain treatments. For polymer P3HT:PCBM, both solvent annealing and thermal annealing can be utilized. The slow growth rate of the active layer when the BHJ film undergoes solvent annealing, allows the P3HT polymer chains to be organized into a highly ordered crystalline state. This improves the polymer's ability to absorption light, enhances the charge carrier mobility, improves the exciton generation and dissociation efficiency, and results in a highly balanced charge carrier transport. High carrier mobility is achieved and allows much thicker active layers to be applied, which makes the solar cell more durable to physical damage during lamination and it also improves the yield of solar cell.

Thermal annealing has also been used to partially recover the polymer crystallinity as well as to improve the solar cell performance. Other possible methods may include solvent mixing, adding ionic salt into the active layer and other interfacial layer modification.

The present disclosure includes two methods to achieve a tandem solar cell. The first method involves stacking multiple solar cells together where two complete polymer solar cells (each having a polymer blend active layer) are stacked and can be connected either in series or in parallel. In method two, two individual polymer solar cells are first constructed and then laminated together to form a tandem structure.

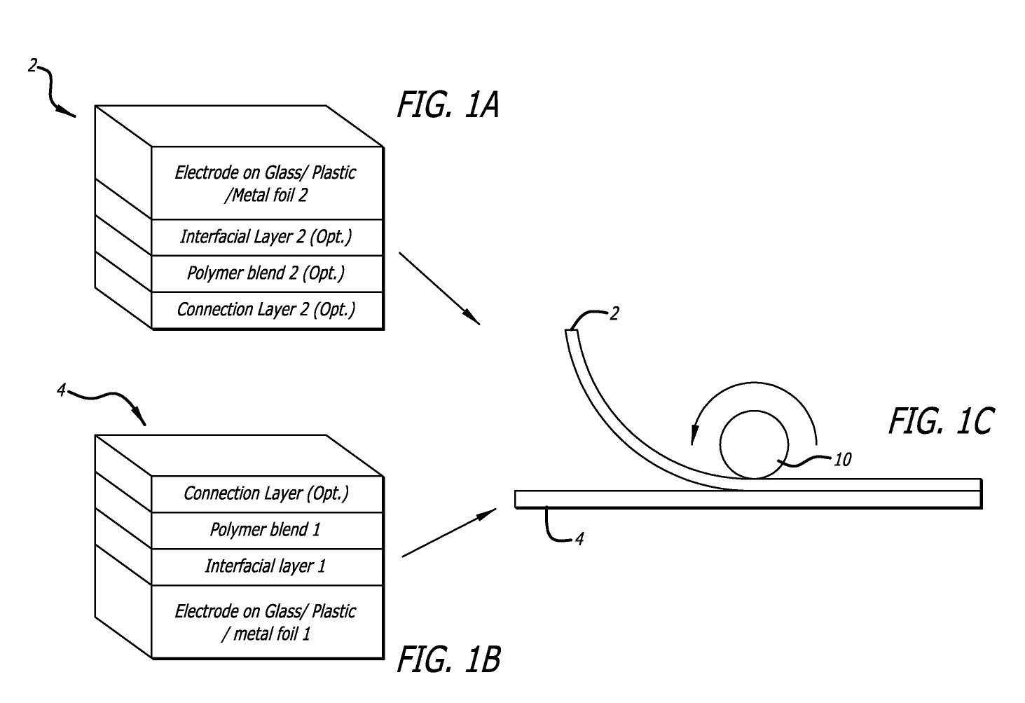

The typical lamination process for plastic solar cell is shown in FIG. 1 in which an active layer or layers are sandwiched between two substrates coated with electrodes. Of the two substrates, preferably at least one is flexible to facilitate the lamination and at least one of the substrates has a polymer blend layer that is an active photovoltaic (PV) layer.

In one embodiment, only substrate 1 is coated with active PV layer and substrate 2 can be coated with interfacial layer 2. In such an instance, interfacial layer 1 is n-type while interfacial layer 2 is p-type and vice versa. When both of substrate 1 and substrate 2 are coated with a polymer blend or blends, interfacial layer 1 and 2 will have opposite polarities as will connection layer 1 and connection layer 2 such that one will be for electron transport/injection and one for will be for hole transport/injection. The two polymer blends can be chosen cover different ranges of the solar spectrum. In some instances, the two polymer blends can be chosen with some degree of overlap or they can be chosen to cover the same ranges of the solar spectrum. The connection layer can be made from the same material as the interfacial layer. For example, the material can be a PEODT:PSS derivative such as a conducting glue used as the p-type material and TiO2, Cs2CO3 as the n-type.

The active layer(s) in organic solar cells include a p-type electron donor material and an n-type electron acceptor material, either in layered structure or in one mixture layer or a combination thereof. Polymer solar cells typically include a bulk-heterojunction (BHJ) of a p-type donor polymer and an n-type acceptor material. The photons are absorbed in the donor polymer and/or acceptor, and the excitons are generated upon photoabsorption. The generated excitons migrate to the donor-acceptor interface, where they are dissociated into free electrons and holes or polarons, and are then transported through a 3-dimensional (3-D) interpenetrated network of donor and acceptor in the BHJ film and are collected at the contacts.

Many polymers such as P3HT, poly[2-methoxy-5-(3,7-dimethyloctyloxy)-1,4-phenylene vinylene] (MDMO-PPV), or poly(2-methoxy-5-(2′-ethyl-hexyloxy)-1,4-phenylene vinylene) (MEH-PPV) can be used as the donor in the BHJ layer. The bandgap of polymers are normally higher than inorganic solar cell materials. For example, P3HT has bandgap of 1.9 ev, compared to silicon's 1.1 ev. This leads to less efficient light harvesting. Low-bandgap polymers have been studied to be used for the active layer and several have shown promise, for example, polymers based on alternating thieno[3,4-b]thiophene and benzodithiophene units and PSBTBT, for applications in solar cells. The integration of high- and low-bandgap polymers to harvest the solar spectrum represents a step towards higher polymer-solar cell performance. The integration can be applied in tandem cell or multiple-device stacking schemes.

The most common candidate for the acceptor materials are PCBM or [6,6]-phenyl C71-butyric acid methyl ester (C70-PCBM). Other materials such as single-walled carbon nanotubes (CNTs) and other n-type polymers can also be used as the acceptor. The active layer can be obtained by spin-coating a polymer solution of an organic solvent or solvents. The active layer can also be obtained by other solution processing techniques, such as but not limited to, wired bar-coating, inkjet-printing, doctor-blading, spray coating, screen printing and other techniques known in the art. Additionally, combinations of these techniques and lamination processes can produce large-area polymer-solution coating and solar cell fabrication techniques with relatively little cost. Flexible substrates may be used to substitute glass allowing the solar cell to be flexible. The flexible substrates can also be chosen to be translucent.

To improve the photovoltaic conversion efficiency of the plastic solar cell, the BHJ film may undergo a variety of treatments. For example, a P3HT:PCBM active layer may utilize solvent annealing and thermal annealing. Utilizing solvent annealing, the slow growth rate of the active layer allows the P3HT polymer chains to be organized into a highly ordered crystalline state, which improves the absorption of light by the polymer, enhances the charge carrier mobility, improves the exciton generation, dissociation efficiency, and results in high balanced-charge carrier transport. This allows enhancement of the efficiency of plastic solar cells utilizing such solvent annealing. The high carrier mobility achieved in this approach also allows much thicker active layers to be applied, which makes the device more endurable to possible physical damages during the lamination process and to improve the yield of the solar cell.

Thermal annealing has also been used to partially recover the polymer crystallinity as well as to improve the solar cell performance. Other possible approaches may additionally include solvent mixing, adding ionic salt into the active layer, as well as other interfacial layer modifications known in the art.

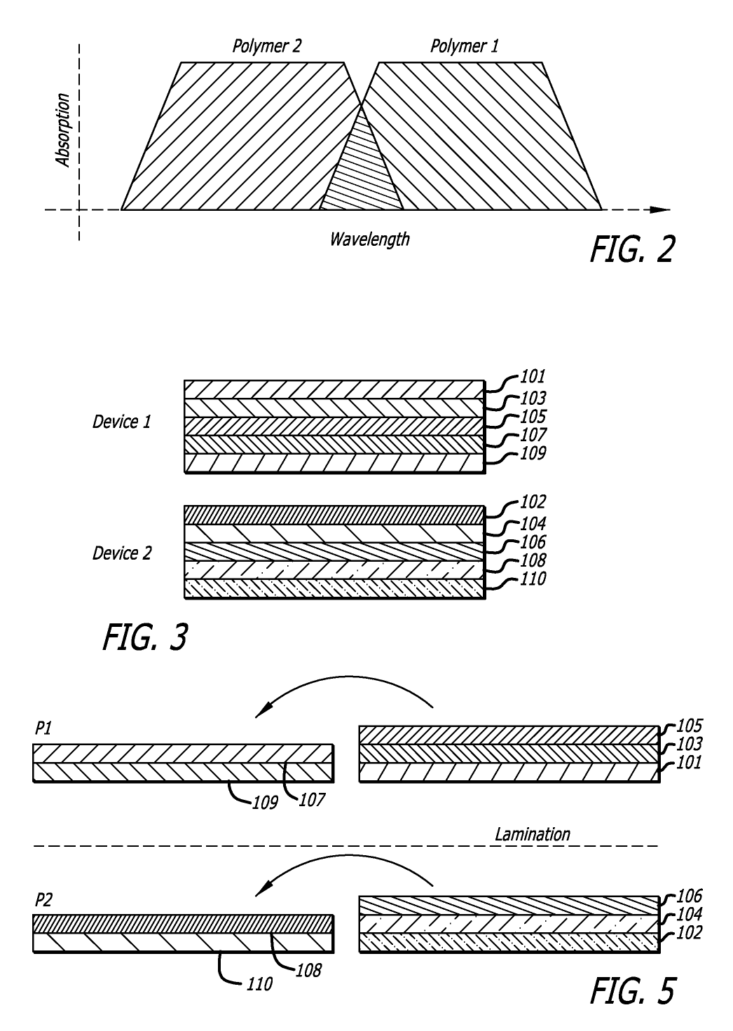

FIG. 2 shows an absorption versus wavelength graph for two polymers used for active layers. In some instances the polymers are chosen to cover different regions of the solar spectrum with some overlap.

In one embodiment, FIGS. 3 and 5 show a lamination formation of two polymer solar cells with the two polymers covering different regions of solar spectrum, in accordance with the present disclosure. Device 1 has an electrode-coated substrate 109 with a layer of conducting glue 107. On top of the layer of conducting glue 107 are a polymer blend layer 105, an interfacial layer 103 on top of the polymer blend layer 105 and an electrode-coated substrate 101. Device 2 has an electrode-coated substrate 110 with a layer of conducting glue 108. On top of the layer of conducting glue 108 are a polymer blend layer 106, an interfacial layer 104 on top of the polymer blend layer 106 and an electrode-coated substrate 102.

Device 1 and Device 2 are stacked and laminated together. In principle, the multiple-device stacking scheme allows any number of sub or component cells in one combined device. At least one solar cell is translucent, for example FIGS. 3 and 5, device 2, such that both of the electrode-coated substrates are transparent to allow light to pass through.

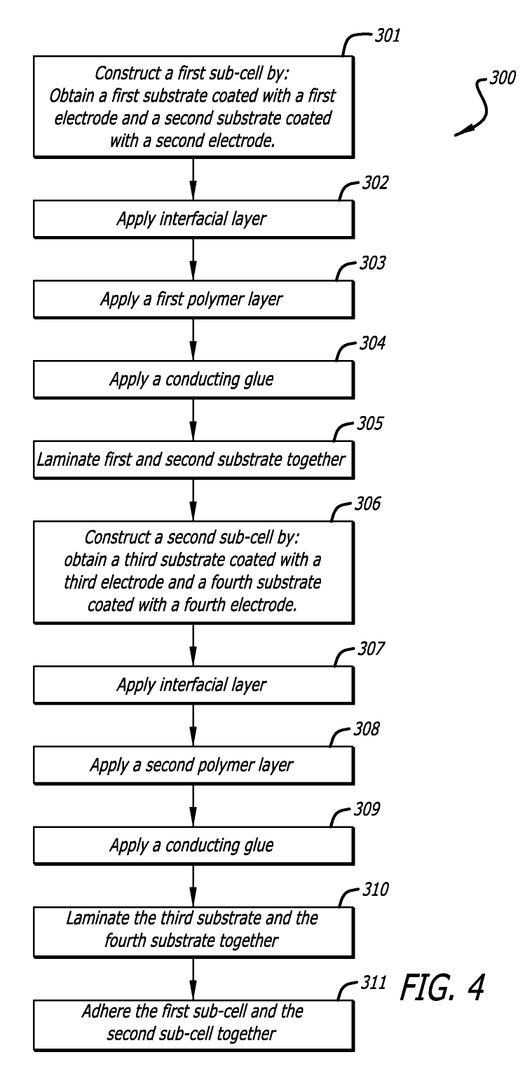

Referring to FIG. 4, there is a process flow diagram for a method 300 for fabricating a tandem polymer solar cell with a single active layer. The method comprises constructing a first sub-cell by obtaining a first substrate 109 coated with a first electrode and a second substrate 101 coated with a second electrode in operation 301. In one instance, at least one of the first substrate coated with the first electrode and the second substrate coated with the second electrode is transparent to allow light to travel through. An interfacial layer 103 is applied on the second electrode of the second substrate 101 in operation 302. A first polymer layer 105 is applied on the interfacial layer 103 of the second substrate 101 in operation 303. A conducting glue layer 107 is applied on one of the first electrodes of the first substrate 109 and the first polymer 105 of the second substrate 109 in operation 304. The first substrate 109 and the second substrate 101 are laminated together such that the first polymer layer 105 of the second substrate 101 is separated from the first electrode of the first substrate 109 by the conducting glue layer 107 in operation 305.

A second sub-cell is constructed by obtaining a third substrate 110 coated with a third electrode and a fourth substrate 102 coated with a fourth electrode in operation 306. In one instance, at least one of the third substrates 110 coated with the third electrode and the fourth substrate 102 coated with the fourth electrode is transparent. An interfacial layer 104 is applied on the fourth substrate 102 and fourth electrode in operation 307 and a second polymer layer 106 is applied on the interfacial layer 104 of the fourth substrate in operation 308. A conducting glue layer 108 is applied on one of the third electrodes of the third substrate 110 and the second polymer 106 of the fourth substrate 102 in operation 309. In operation 310, the third substrate 110 and the fourth substrate 102 are laminated together such that the second polymer layer 106 of the fourth substrate 102 is separated from the third electrode of the third substrate 110 by the conducting glue layer 108. The first sub-cell and the second sub-cell are adhered together with a refraction index-matching glue such that light will go through the first sub-cell to the second sub-cell.

The first polymer layer 105 and the second polymer layer 106 can be chosen to absorb different regions of the solar spectrum, as illustrated in FIG. 2, or they could be made from the same polymer blend for absorbing the same region of the solar spectrum. In order for light to be transmitted through to the tandem cell, at least one of the first sub-cell and second sub-cell must have two transparent electrodes. The electrode of the third substrate 110 or bottom substrate can be opaque because it may not be necessary to have light transmit through the entire solar cell. The bottom electrode can thus be an opaque material such as a metal foil or a metal film.

For lamination, at least one of the substrates is flexible. It can either be plastic film or metal foil (latter one for opaque electrode). Glass or plastic or metal can be used as a rigid substrate. The transparent electrode can be, but is not limited to: (a) transparent conductive oxides (TCOs) such as indium tin oxide (ITO), fluorinated tin oxide (FTO) etc.; (b) high conductivity polymers, such as high conductivity poly(ethylene dioxythiophene):poly(styrenesulfonate) (PEDOT:PSS) or polyaniline (PANI); and (c) fine metal line/grid combined with (a) and (b). Opaque electrodes can be a metal foil, metal films on glass or plastic. A roller can be used to laminate the substrates together and the conducting glue can be heated to make it adhere to its respective substrate.

For maximizing the polymer solar cell performance, the respective interfacial layers and the respective conducting glue layers should have a different polarity, i.e., one is n-type, and the other one is p-type. Conducting glue plays an important role as (a) carrier transport/injection/extraction and (b) physical binding of the substrates upon lamination. A PEDOT:PSS based conducting glue (e.g., by doping with D-sobitol) has been successfully applied on organic electronic devices such as polymer light-emitting devices and polymer solar cells. Such formed conducting or electronic glue is p-type. However, the conducting glue can also be made from an n-type material.

An interfacial layer is used to modify the interface between electrode and polymer blend active layers and also to improve performance. Typical n-type interfacial layers may include salts such as carbonates, fluorides, oxides and others with low work-function metals such as Cs2CO3, CsF, LiF, CaO and others. Transition metal oxides (TMOs) such as titanium oxide (TiO2, TiOx), zinc oxide (ZnO), gallium oxide (GaO), or compound oxides such as magnesium-doped zinc oxide (ZnMgO) and others can also be used.

Typical p-type interfacial layer materials include high conducting polymers, such as PEDOT:PSS, or PANI; transition metal oxides (TMOs) such as vanadium pentoxide (V2O5), molybdenum oxide (MoO3), or tungsten oxide (WO3); high work function metals such as Au, Pt, Pd and others. The interfacial layers can be applied by thermal evaporation, sputtering, solution process or sol-gel processing.

Depending on the substrate and electrodes, either flexible or rigid, either transparent or opaque solar cells can be fabricated. In multiple-device stacking, fully functional individual solar cells can be interconnected. Each sub-cell has its own positive and negative electrodes. Compared to traditional tandem solar cells where the sub-cells must be connected in series, multiple-device stacking allows the sub-cells to be connected in parallel, or a combination of series and parallel when more than two cells are used. This feature can be helpful in improving performance when the sub-cells a have similar photovoltage but different photocurrents. The sub-cells can be all transparent cells or have one opaque cell.

When light is shown on an air/substrate interface, the light's intensity will decrease due to the difference in refraction index of the air and the substrate. A tandem solar cell has many such interfaces and these additional interfaces each lead to a further decrease in light intensity. An index-matching glue or epoxy is used to bind the individual cells to help decrease such a loss in light intensity. The index of refraction of the epoxy can be tuned to minimize such a decrease. The effectiveness of this technique has been demonstrated where the light loss utilizing such an epoxy to bond two pieces of glass is significantly less relative to a two-piece glass configuration without such a bond.

In the traditional tandem solar cell, more than two sub-cells were grown on a single substrate with sub-cells connected by connection unit(s) and these sub-cells are connected in series to form tandem structure. Lamination approach can also replicate this structure with one additional substrate.

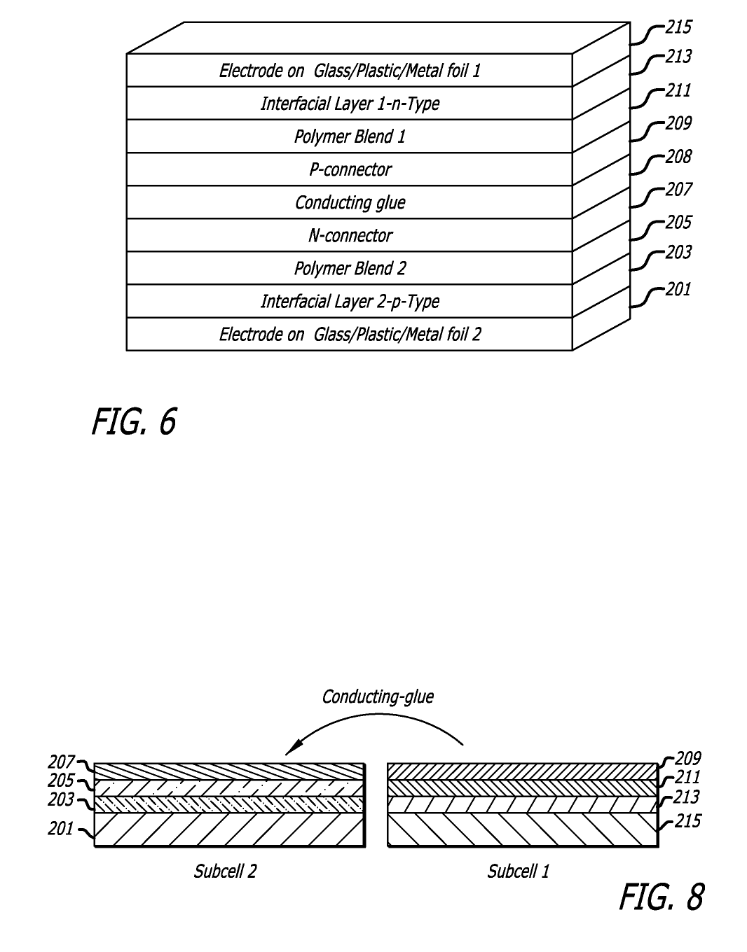

Referring to FIG. 6, there is a tandem polymer solar cell 600 in accordance with the present disclosure. The tandem solar cell 600 includes a first sub-cell 1 that has a substrate 215 that can be plastic or glass with an electrode deposited thereon. On top of the substrate 215 there is an n-type interfacial layer 213 and a first polymer blend layer 211 deposited on the n-type interfacial layer 213. On top of the first polymer blend layer 211 there is a p-type connection layer 209. There is a conducting glue layer 208 that adheres the first sub-cell 1 to a second sub-cell 2 between the p-type connection layer 209 of sub-cell 1 and an n-type connection layer 207 of sub-cell 2. Between there is a second polymer blend layer 205 between the n-type connection layer 207 and a p-type interfacial layer 203. The p-type interfacial layer 203 is on top of an electrode-covered substrate 201 of sub-cell 2.

The polarity of sub-cell 1 and sub-cell 2 must be correct to form a working solar cell. As described earlier, the interfacial layers 203 and 213 and connector layers 207 and 209 must have opposite polarities, i.e., one is n-type and the other one is p-type. On the other hand, the connection layers 207 and 209 must be different for the combined device to function correctly.

Sub-cell 2 is a so-called inverted device configuration, i.e., there is an n-type interfacial layer on top of substrate, then a polymer blend active layer covered with p-type connector layer. In the regular structure the bottom contact is the anode, which collects holes, and the top contact is the cathode which collects electrons during the energy conversion. The polarity is reversed in the inverted cell configuration; bottom contact is the cathode and top contact is the anode. The materials used for the n-type and p-type connector layers are the same as described above for interfacial layers.

The electronic glue can be either n-type or p-type. It is therefore possible to replace either the n-type or p-type connector in one of the sub-cells. In such a case, the connection layers, n-connector/Electronic glue/p-connector, can be simplified to either n-connector/p-electronic glue or n-electronic glue/p-connector.

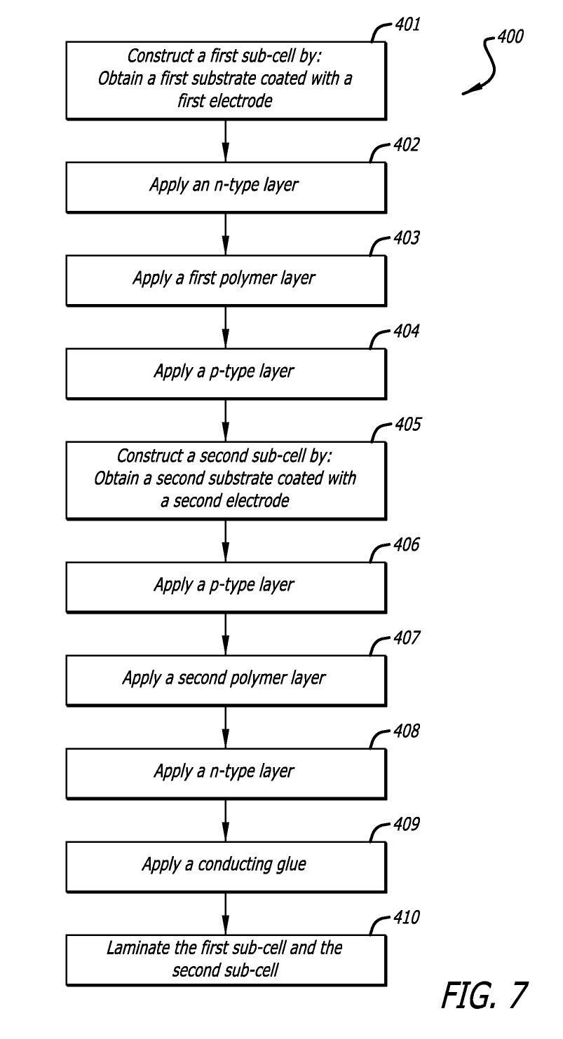

Referring to FIG. 7, there is a process flow diagram for a method 400 for fabricating a tandem polymer solar cell with two active layers. The method 400 begins by constructing a first sub-cell by obtaining a first substrate 215 coated with a first electrode in initiation operation 401. Using the first substrate coated with the first electrode, a first sub-cell is constructed by applying an n-type layer 213 on the first electrode of the first substrate 215 in operation 402. A first polymer blend layer 211 is applied on the n-type layer 213 in operation 403 and a p-type layer 209 is applied on the first polymer blend layer 211 in operation 404. A second sub-cell is constructed by obtaining a second substrate 201 with a second electrode thereon in operation 405. A p-type interfacial layer 203 is applied on the second electrode of the second substrate 201. A second polymer blend layer 205 is applied on the p-type interfacial layer 203. An n-type connector layer 207 is applied on the second polymer layer 205 and a conducting glue 208 is applied on either the p-type layer 209 of the first sub-cell or the n-type layer 207 of the second sub-cell. The first and second sub-cells are laminated together such that the conducting glue 208 adheres the p-type layer 209 of the first sub-cell to the n-type layer 207 of the second sub-cell. The first polymer layer 211 and the second polymer-blend layer 205 can absorb different regions of the solar spectrum or they can cover the same region of the solar spectrum.

The first and second electrodes can be a transparent conducting oxide. The n-type layer 213 of the first sub-cell and the n-type connection layer 207 of the second sub-cell can be one of Cs2CO3, LiF, CsF, TiOx and a mixture of TiOx:Cs2CO3. The p-type connection layer 209 of the first sub-cell and the p-type layer 203 of the second sub-cell can be one of V2O5, WO3, MoO3 and PEDOT:PSS.

Having a transparent electrode, multiple device stacking and double-sub-cell tandem solar cells can have multiple active layers. In general, one (or more) double-sub-cell tandem solar cell(s) plus one (or more) single active layer can be produced.

In one embodiment, the lamination process can involve flexible substrates and encapsulation methods that are developed to prevent oxygen and water from penetrating the substrates in the vertical direction. If the solar cell is rigid, such as a substrate made from glass, no additional encapsulation is needed. The counter substrate (outmost) of the whole device is flexible. However, because this substrate is not required to be transparent, stainless steel or other stable metal foils for encapsulation can be utilized. This could be done by using a stainless steel foil as the substrate (work-function modification may be required); or using stainless steel foil as the encapsulation material, where it can be laminated on the flexible substrate to be protected by an epoxy/resin.

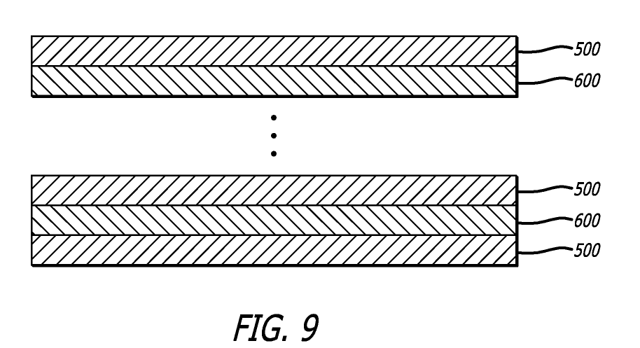

While one substrate can be made from a metal foil as described above, the encapsulation of a flexible transparent substrate such as plastic can be challenging. To address this challenge, a multiple layer structure with repeated plastic and thermal curable resin units, shown in FIG. 9, are proposed. During the lamination process, plastic substrates 500 are bonded together by the resin layers 600 when heat is applied. The resin is blended with a desiccant to absorb any oxygen and water that may be present. The desiccant particles are chosen to be small enough so that the resin-desiccant can form a smooth and uniform film and so that the film is transparent with minimal light scattering. The latter is to guarantee efficient light incidence into the active polymer layers. The concentration of desiccant is chosen so that when it absorbs oxygen and water, large particle aggregation does not occur because large particle aggregation could deform the film and/or scatter incident light. Materials such as calcium oxide (CaO), magnesium oxide (MgO), cesium fluoride (CsF), cesium carbonate (Cs2CO3) and others can be used as the desiccant.

Thus, multiple-stacking and tandem polymer solar cells using a lamination process in accordance with the present disclosure have an intrinsic advantage over other polymer solar cell fabrication processes in that the methods are a vacuum-free process with lower manufacturing costs, compatible with flexible substrates and roll-to-roll fabrication, compatible with transparent or translucent polymer solar cells and they have potentially higher efficiency made possible through improved light harvesting of multiple active layers.

Multiple-device stacking and tandem polymer solar cells have the ability to create architecturally aesthetic applications by integrating our cells onto glass, glass laminates, or flexible substrates of virtually any shape of surface on any building and transportation windows, thus allowing triple functions of power generation, light filtration, and architectural element/aviation, automotive, and marine design.

While the apparatus and methods have been described in terms of what are presently considered to be the most practical and preferred embodiments of Multiple-device stacking and tandem polymer solar cells, it is to be understood that the disclosure need not be limited to the disclosed embodiments. It is intended to cover various modifications and similar arrangements included within the spirit and scope of the claims, the scope of which should be accorded the broadest interpretation so as to encompass all such modifications and similar structures. The present disclosure includes any and all embodiments of the following claims.

1. A method of fabricating a tandem polymer solar cell having a single active layer, the method comprising:
constructing a first sub-cell by:
obtaining a first substrate coated with a first electrode and a second substrate coated with a second electrode, wherein at least one of the first substrate coated with the first electrode and the second substrate coated with the second electrode is transparent;
applying an interfacial layer on the second electrode of the second substrate;
applying a first active layer on the interfacial layer of the second substrate;
applying a conducting glue on one of the first electrodes of the first substrate and the first active layer of the second substrate; and
laminating the first substrate and the second substrate together such that the first active layer of the second substrate is separated from the first electrode of the first substrate by the conducting glue;
constructing a second sub-cell by:
obtaining a third substrate coated with a third electrode and a fourth substrate coated with a fourth electrode, wherein at least one of the third substrates coated with the third electrode and the fourth substrate coated with the fourth electrode is transparent;
applying an interfacial layer on the fourth substrate and fourth electrode;
applying a second active layer on the interfacial layer of the fourth substrate; and
applying a conducting glue on one of the third electrodes of the third substrate and the second active layer of the fourth substrate; and
laminating the third substrate and the fourth substrate together such that the second active layer of the fourth substrate is separated from the third electrode of the third substrate by the conducting glue; and
adhering the first sub-cell and the second sub-cell together with a reflection index-matching glue such that light will go through the first sub-cell to the second sub-cell.

2. The method of claim 1, wherein the first active layer and the second active layer absorb different regions of the solar spectrum.

3. The method of claim 1, wherein the first active layer and the second active layer are the same polymer blend.

4. The method of claim 1, wherein at least one of the first sub-cells and second sub-cells are transparent.

5. The method of claim 1, wherein at least one of the first sub-cells and second sub-cells have two transparent electrodes.

6. The method of claim 1, wherein at least one roller is used when laminating the substrates together.

7. The method of claim 1, further comprising heating the conducting glue of at least the first substrate and third substrate to make the conducting glue adhere the second substrate and fourth substrate respectively.

8. The method of claim 1, wherein the electrode of the fourth substrate is opaque and is a metal foil or a metal film.

9. The method of claim 1, wherein at least one of the substrates is flexible.

10. A method of fabricating a tandem polymer solar cell having two active layers, the method comprising:
constructing a first sub-cell by:
obtaining a first substrate coated with a first electrode;
applying an n-type layer on the first electrode;
applying a first active layer on the n-type layer; and
applying a p-type layer on the first active layer;
constructing a second sub-cell by:
obtaining a second substrate with a second electrode;
applying a p-type layer on the second electrode;
applying a second active layer on the p-type layer
applying an n-type layer on the second active layer; and
applying a conducting glue on one of the p-type layer of the first sub-cell or the n-type layer of the second sub-cell; and
laminating the first sub-cell and the second sub-cell together such that the conducting glue adheres the p-type layer of the first sub-cell to the n-type layer of the second sub-cell.

11. The method of claim 10, wherein the first active layer and the second active layer absorb different regions of the solar spectrum.

12. The method of claim 10, wherein the first active layer and the second active layer are the same polymer blend.

13. The method of claim 10, wherein at least one of the first sub-cells and second sub-cells are transparent.

14. The method of claim 10, wherein at least one roller is used when laminating the substrates together.

15. The method of claim 10, further comprising heating the conducting glue to make the conducting glue adhere to the p-type layer of the first sub-cell and to the n-type layer of the second sub-cell.

16. The method of claim 10, wherein the first electrode is opaque and is a metal foil or a metal film.

17. The method of claim 10, wherein the second electrode is opaque and is a metal foil or a metal film.

18. The method of claim 10, wherein the first electrode is a transparent conducting oxide.

19. The method of claim 10, wherein the second electrode is a transparent conducting oxide.

20. The method of claim 10, wherein the n-type layer of the first sub-cell and the second sub-cell are one of Cs2CO3, LiF, CsF, TiOx and a TiOx:Cs2CO3 mixture.

21. The method of claim 10, wherein the p-type layer of the first sub-cell and the second sub-cell are one of V2O5, WO3, MoO3 and PEDOT:PSS.

22. The method of claim 10, wherein at least one of the first substrate and second substrate are flexible.
